(19) United States
(12) Patent Application Publication
(10) Pub. No.: US 2018/0219118 A1
(43) Pub. Date: Aug. 2, 2018

(54) BACK CONTACT PHOTOVOLTAIC CELLS WITH INDUCED JUNCTIONS

(71) Applicants: IMEC vzw, Leuven (BE); Kuwait University, Safat (KW)

(72) Inventors: Jef Poortmans, Kassel-Lo (BE); Moustafa Ghannam, Zamalek (EG); Yaser Abdulraheem, Leuven (BE)

(21) Appl. No.: 15/881,500

(22) Filed: Jan. 26, 2018

Related U.S. Application Data
(63) Continuation of application No. PCT/EP2016/065372, filed on Jun. 30, 2016.

(30) Foreign Application Priority Data
Jul. 28, 2015 (EP) 15178675.3

(51) Int. Cl. H01L 31/062; H01L 31/0224; H01L 31/18

(52) U.S. Cl. CPC H01L 31/062; H01L 31/022475; H01L 31/022483; H01L 31/02363; H01L 31/1868; H01L 31/1884; H01L 31/1804

(57) ABSTRACT

The disclosed technology generally relates to photovoltaic devices and more particularly to back contact photovoltaic devices, and to methods of fabricating back contact photovoltaic devices. In one aspect, a back contact photovoltaic cell includes an n-type silicon substrate having formed on a rear side first layer stacks formed at first locations and second layer stacks formed at second locations different from and non-overlapping with the first locations. Each of the first layer stacks includes a passivating tunneling layer and a first transparent conductive layer having a first work function, where the first transparent conductive layer induces an inversion region in the n-type silicon substrate at a corresponding one of the first locations, where the inversion region forms an emitter region of the back contact photovoltaic cell. Each of the second layer stacks induces an accumulation region in the n-type silicon substrate at a corresponding one of the second locations, where the accumulation region forms a back-surface field region of the back contact photovoltaic cell.

### CROSS-REFERENCE TO RELATED APPLICATIONS

This application is a continuation of International Patent Application PCT/EP2016/065372, filed Jun. 30, 2016, which claims foreign priority to European Patent Application No. EP 15178675.3, filed Jul. 28, 2015. The content of each is incorporated by reference herein in its entirety.

### BACKGROUND

### Field

The disclosed technology generally relates to photovoltaic devices and more particularly to back contact photovoltaic devices, and to methods of fabricating back contact photovoltaic devices.

### Description of the Related Technology

Back contact photovoltaic devices, including silicon-based back contact photovoltaic devices, have a pattern of p-doped regions and n-doped regions and corresponding p-type contacts and n-type contacts formed at the rear side of the device, instead of the front side of the device that is configured to receive incident sunlight. One type of back contact photovoltaic devices is interdigitated back contact (IBC) photovoltaic devices.

While back contact devices offer various advantages, including larger surface area available to harvest sunlight, fabrication processes for back contact photovoltaic devices, e.g., IBC photovoltaic devices, can be relatively complex and costly. For example, when an IBC cell structure is based on an interdigitated pattern of homo-junction emitter regions and back surface field regions at the rear side, care has to be taken to separate these differently doped regions from each other, e.g., to avoid shunting of the cells. Additionally, the dopant diffusion steps used to realize the high doping levels may employ a relatively high thermal budget, which can be disadvantageous for various reasons. For example, the high thermal budget may reduce bulk minority carrier lifetimes, which values are desired to be relatively high for optimal performance of the back-contacted photovoltaic cells.

In some fabrication process flows for heterojunction IBC cells, an interdigitated pattern of differently doped amorphous silicon layers is deposited on the rear side of a crystalline silicon substrate. The amorphous silicon layers forming the heterojunctions at the rear side typically include a stack of several layers, for example a few nm-thin intrinsic amorphous silicon layer for interface passivation having formed thereon either a highly p-type doped amorphous Si layer (e.g., for forming the emitter regions) or a highly doped n-type amorphous Si layer (e.g., for forming heterojunction contacts to the base). The need for providing such a stack of layers can result in a relatively complex fabrication process. On top of such stacks of amorphous silicon layers, a transparent conductor layer and a metal contact layer are typically deposited. The transparent conductor layer separates the amorphous silicon layer from the metal contacts, thereby reducing optical losses and enhancing the back surface reflection.

In “Diffusion-free back-contact cells on S-passivated p-type Si(100) substrates”, Proceedings of the 33^{rd} IEEE Photovoltaic Specialist Conference, 2008, G. Song et al describe back contact photovoltaic cells based on a p-type crystalline silicon substrate with a field-induced p-n junction. The p-n junction is formed by a high Schottky barrier between low work-function aluminum and a sulfur-passivated p-type Si(100) surface. The sulfur passivation is performed in an aqueous solution of (NH₄)₂S. The high Schottky barrier induces degenerate inversion on the surface of the p-type silicon, leading to the formation of a p-n junction without the need for a dopant diffusion step. However, the observed photovoltaic cell conversion efficiency was low (about 1%), which can be attributed to two factors: surface passivation quality and minority carrier lifetime. Thus, there is a need for back contact photovoltaic devices and their fabrication methods, which are capable of providing relatively higher conversion efficiency.

### SUMMARY OF CERTAIN INVENTIVE ASPECTS

The present disclosure aims to provide back contact photovoltaic devices or cells, such as interdigitated back contact photovoltaic cells, with good conversion efficiency, and methods for fabricating such back contact cells. Using a fabrication method in accordance with an embodiment of the present disclosure, the number of process steps is reduced as compared to known fabrication methods, resulting in a reduced complexity of the fabrication process as compared to known methods.

According to an embodiment of the present disclosure, there is provided a method of fabricating back contact photovoltaic cells, such as interdigitated back contact photovoltaic cells, wherein the photovoltaic cells can be fabricated at relatively low temperatures, such as for example at temperatures not exceeding 600° C.

According to an embodiment of the present disclosure, there is provided a back contact photovoltaic cell, such as an interdigitated back contact photovoltaic cell, that can be fabricated using a low temperature fabrication process, e.g., a fabrication process that is performed at temperatures not exceeding 600° C., with a reduced number of process steps as compared to known fabrication methods, wherein the photovoltaic cell has a good energy conversion efficiency, and wherein the photovoltaic cell has an open-circuit voltage above 700 mV.

The present disclosure provides a back contact photovoltaic cell comprising a silicon substrate, e.g., a single crystalline or polycrystalline silicon substrate, and comprising at a back side or rear side of the silicon substrate an emitter region at first predetermined locations and a back surface field region at second predetermined locations, wherein the second predetermined locations are different from and non-overlapping with the first predetermined locations, and wherein the emitter region and the back surface field region are field-induced regions.

According to an embodiment of the present disclosure, the back contact photovoltaic cell may comprise a first layer stack on the rear surface of the silicon substrate at the first predetermined locations. The back contact photovoltaic cell may further comprise a second layer stack on the rear surface of the silicon substrate at the second predetermined locations. The first layer stack, e.g., a material or a combination of materials of the first layer stack, may be selected to induce an inversion region in the silicon substrate at the first predetermined locations, the inversion region forming (e.g., corresponding to) the emitter region. The second layer stack, e.g., a material or a combination of materials of the second layer stack, may be selected to induce an accumulation region in the silicon substrate at the second predetermined locations, the accumulation region forming (e.g., corresponding to) the back surface field region.

According to an embodiment of the present disclosure, the silicon substrate, which may be monocrystalline or polycrystalline, may, for example, be an n-type silicon substrate. The back contact photovoltaic cell may comprise a first layer stack on the rear surface of the silicon substrate at the first predetermined locations, the first layer stack comprising a passivating tunneling layer and a first transparent conductive layer comprising a material with a high work function. The high work function material of the first transparent conductive layer may be selected to induce the emitter region at the first predetermined locations. The high work function material of the first transparent conductive layer may, for example, have a work function in the range between 5 eV and 6 eV, the present disclosure not being limited thereto. The back contact photovoltaic cell may further comprise a second layer stack on the rear surface of the silicon substrate at the second predetermined locations, the second layer stack comprising a passivating tunneling layer and a second transparent conductive layer comprising a material with a low work function. The low work function material of the second transparent conductive layer may be selected to induce a back surface field region at the second predetermined locations. The low work function material of the second transparent conductive layer may for example have a work function in the range between 3.5 eV and 4.5 eV, the present disclosure not being limited thereto.

In a photovoltaic cell according to an embodiment of the present disclosure, the emitter region (inversion region) is induced as a result of the presence of the passivating tunneling layer and the first transparent conductive layer at the first predetermined locations. The back surface field region (accumulation region) is induced as a result of the presence of the passivating tunneling layer and the second transparent conductive layer at the second predetermined locations.

Surface recombination can have a negative impact both on the short-circuit current and on the open-circuit voltage of the back contact photovoltaic cells. The passivating tunneling layer serves, among other functions, to lower the rate of surface recombination by reducing the number of dangling silicon bonds at the surface. The passivating tunneling layer may for example be a thin dielectric layer, such as for example a thin silicon oxide layer or a thin intrinsic amorphous silicon layer, or a monolayer of a passivating atomic species, such as for example a S or Se monolayer or a Cl monolayer, the present disclosure not being limited thereto. The thickness of the dielectric layer may for example be in the range between 1 nm and 5 nm, for example between 1 nm and 3 nm, for example between 1 nm and 2 nm, the present disclosure not being limited thereto.

The first layer stack may further comprise a first metal layer or first metal stack on the first transparent conductive layer and the second layer stack may further comprise a second metal layer or second metal stack on the second transparent conductive layer.

The first transparent conductive layer and/or the second transparent conductive layer may comprise a stack of at least two layers, e.g., a stack of two layers.

In an embodiment of the present disclosure, the first predetermined locations may be interdigitated with the second predetermined locations.

The disclosure further provides a method of fabricating a back contact photovoltaic cell. The method comprises providing at first predetermined locations on a rear surface of a silicon substrate a first layer stack, wherein the first layer stack induces an inversion region (emitter region) in the silicon substrate at the first predetermined locations. The method additionally comprises providing at second predetermined locations on the rear surface of the silicon substrate a second layer stack, wherein the second layer stack induces an accumulation region (back surface field region) in the silicon substrate at the second predetermined locations. The second predetermined locations are different from and non-overlapping with the first predetermined locations.

According to an embodiment of the present disclosure, the silicon substrate, which may be monocrystalline or polycrystalline, may for example be an n-type silicon substrate. A method according to an embodiment of the present disclosure may comprise providing at the first predetermined locations on the rear surface of the silicon substrate a first layer stack, wherein providing the first layer stack comprises providing a passivating tunneling layer on the rear surface of the silicon substrate and providing a first transparent conductive layer comprising a material with a high work function, e.g., a work function in the range between 5 eV and 6 eV, on the passivating tunneling layer at the first predetermined locations. The method may further comprise providing at the second predetermined locations on the rear surface of the silicon substrate a second layer stack, wherein providing the second layer stack comprises providing a passivating tunneling layer on the rear surface of the silicon substrate and providing a transparent conductive layer comprising a material with a low work function, e.g., a work function in the range between 3.5 eV and 4.5 eV, on the passivating tunneling layer at the second predetermined locations, the second predetermined locations being different from and non-overlapping with the first predetermined locations.

A fabrication method according to embodiments of the present disclosure may be performed at temperatures not exceeding 600° C.

In a method of the present disclosure, providing the passivating tunneling layer may comprise providing a thin dielectric layer, such as for example a thin silicon oxide layer or a thin intrinsic amorphous silicon layer. Suitable methods may be used for providing the thin dielectric layer such as, e.g., oxidation or deposition.

In a method of the present disclosure, providing the passivating tunneling layer may comprise providing a monolayer of a passivating atomic species, such as for example a S, Se or Cl monolayer. Such monolayer may, for example, be formed by wet chemical processing or by a suitable deposition technique such as chemical vapor deposition or atomic vapor deposition.

In embodiments of the present disclosure, the first transparent conductive layer and/or the second transparent conductive layer may be provided by solution processing.

The method may further comprise providing a first metal layer or a first metal stack on the first transparent conductive layer and providing a second metal layer or a second metal stack on the second transparent conductive layer.

In an embodiment according to the present disclosure, the first predetermined locations may be interdigitated with the second predetermined locations.

It is an advantage of a method of the present disclosure that it can be performed at a lower cost as compared to known fabrication methods for back contact cells photovoltaic cells, e.g., interdigitated back contact photovoltaic cells. The lower cost is related to a reduced number of process steps and/or a reduced thermal budget as compared to known methods for fabricating back contact photovoltaic cells, e.g., interdigitated back contact photovoltaic cells.

It is an advantage of a method of the present disclosure that it enables low temperature fabrication of interdigitated back contact photovoltaic cells, i.e. fabrication at temperatures not exceeding 600° C. It is an advantage of a low temperature fabrication process that it allows maintaining a high bulk minority carrier lifetime.

It is an advantage of a method of the present disclosure and of a photovoltaic device of the present disclosure that the induced emitter region (inversion layer) does not suffer from physical degradation associated with heavy doping, such as for example mobility degradation and/or bandgap narrowing effects. When using an induced emitter, the desired carrier concentrations may be achieved without the risk of doping related degradation.

Certain objects and advantages of various inventive aspects have been described herein above. Of course, it is to be understood that not necessarily all such objects or advantages may be achieved in accordance with any particular embodiment of the disclosure. Thus, for example, those skilled in the art will recognize that the disclosure may be embodied or carried out in a manner that achieves or optimizes one advantage or group of advantages as taught herein without necessarily achieving other objects or advantages as may be taught or suggested herein. Further, it is understood that this summary is merely an example and is not intended to limit the scope of the disclosure. The disclosure, both as to organization and method of operation, together with features and advantages thereof, may best be understood by reference to the following detailed description when read in conjunction with the accompanying drawings.

### BRIEF DESCRIPTION OF THE DRAWINGS

FIG. 1 schematically shows a cross section of a back contact photovoltaic cell in accordance with an embodiment of the present disclosure.

FIG. 2(a) schematically shows a cross section of a structure comprising an n-type silicon substrate having a surface coated with a stack of a 2 nm thin SiO₂ layer and a transparent conductive oxide with a work function of 6 eV.

FIG. 2(b) shows calculated hole and electron concentrations for the structure of FIG. 2(a), illustrating the formation of a p-type inversion layer in a surface region of the substrate, in accordance with an embodiment of the present disclosure.

FIG. 3(a) schematically shows a cross section of a structure comprising an n-type substrate coated with a stack of a 2 nm thin intrinsic amorphous silicon layer and a transparent conductive oxide with a work function of 6 eV.

FIG. 3(b) shows calculated hole and electron concentrations for the structure of FIG. 3(a), illustrating the formation of a p-type inversion layer in a surface region of the substrate, in accordance with an embodiment of the present disclosure.

FIG. 4(a) schematically shows a cross section of a structure comprising an n-type substrate coated with a stack of a 2 nm thin SiO2 layer and a transparent conductive oxide with a work function of 3.5 eV.

FIG. 4(b) shows calculated hole and electron concentrations for the structure of FIG. 4(a), illustrating the formation of an n-type (n⁺) accumulation layer in a surface region of the substrate, in accordance with an embodiment of the present disclosure.

FIG. 5(a) schematically shows a cross section of a structure comprising an n-type substrate coated with a stack of a 2 nm thin intrinsic amorphous silicon layer and a transparent conductive oxide with a work function of 3.5 eV.

FIG. 5(b) shows calculated hole and electron concentrations for the structure of FIG. 5(a), illustrating the formation of an n-type (n⁺) accumulation layer in a surface region of the substrate, in accordance with an embodiment of the present disclosure.

Any reference signs in the claims shall not be construed as limiting the scope of the present disclosure.

In the different drawings, the same reference signs refer to the same or analogous elements.

### DETAILED DESCRIPTION OF CERTAIN ILLUSTRATIVE EMBODIMENTS

In the following detailed description, numerous specific details are set forth in order to provide a thorough understanding of the disclosure and how it may be practiced in particular embodiments. However, it will be understood that the present disclosure may be practiced without these specific details. In other instances, well-known methods, procedures and techniques have not been described in detail, so as not to obscure the present disclosure.

The present disclosure will be described with respect to particular embodiments and with reference to certain drawings but the disclosure is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the disclosure.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising components A and B” should not be limited to devices consisting only of components A and B.

In the context of the present disclosure, the front surface or front side of a photovoltaic cell is the surface or side adapted for being oriented towards a light source and thus for receiving illumination. The back surface, rear surface, back side or rear side of a photovoltaic cell is the surface or side opposite to the front surface or side. The front side of a substrate used to form a photovoltaic cell is the side of the substrate corresponding to the front side of the photovoltaic cell, while the rear side or back side of the substrate corresponds to the back side of the photovoltaic cell.

In the context of the present disclosure, a tunnelling layer is a thin layer, for example a 1 nm to 3 nm thin layer, for example made of an electrically insulating material, wherein charge carriers, e.g., electrons, can pass through the layer by quantum mechanical tunneling instead of by classical drift or diffusion mechanisms. In the context of the present disclosure, a passivating tunnelling layer is a tunnelling layer that has a surface passivating effect, i.e., a layer that reduces the surface state density of the underlying surface, e.g., silicon surface, and as a result reduces the surface recombination velocity.

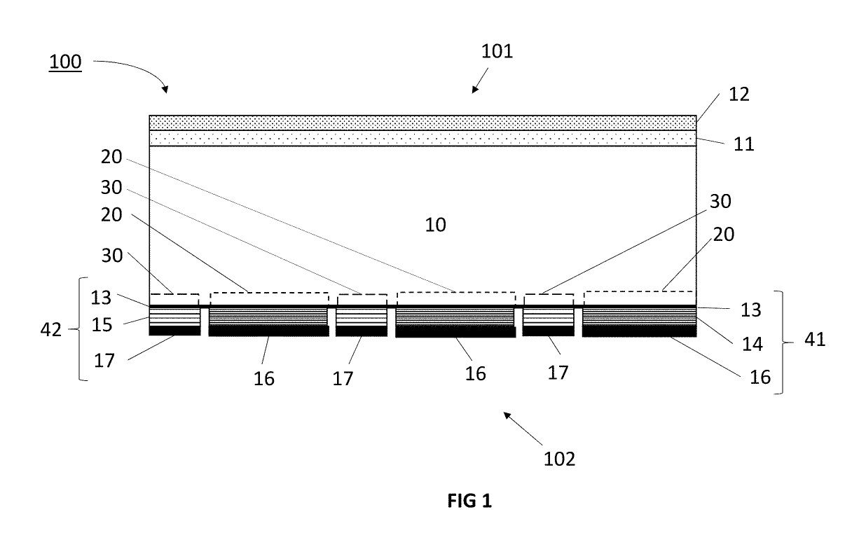

An example of a back contact photovoltaic cell 100 according to an embodiment of the present disclosure is schematically shown in FIG. 1 (cross section). The photovoltaic cell 100 comprises a crystalline silicon substrate 10 (base 10), which can be monocrystalline or polycrystalline. The silicon substrate 10 can be an n-type or a p-type. For illustrative purposes, the illustrated silicon substrate 10 is described herein as being an n-type substrate having electrons as majority carriers and holes as minority carriers. However, the present disclosure is not limited thereto and the substrate 10 may be a p-type substrate. In the further description an n-type substrate 10 is assumed. The substrate 10 preferably has a high minority carrier lifetime and typically has a resistivity in the range between 1 ohm-cm and 10 ohm-cm. The front surface or front side 101 of the photovoltaic cell 100 may be textured (not shown in FIG. 1), to enhance efficiency by, e.g., reducing reflection. The photovoltaic cell 100 may, for example, have a front surface field region 11 and an antireflection coating 12 at the front side 101. The front surface field region may, for example, be formed by diffusion of a dopant of the same type as the substrate 10, which is an n-type dopant in the illustrated embodiment, into the substrate 10. Alternatively, the front surface field region may be field-induced or it may be charge induced, e.g., by providing on the front surface a layer having a high positive charge density, such as for example a silicon nitride layer with a positive fixed charge density.

At the rear side 102 of the cell 100, preferably on the entire rear surface of the cell 100, a passivating tunneling layer 13 is formed. In some embodiments, the passivating tunneling layer 13 can, for example, be a thin dielectric layer such as, for example, a 1 nm to 3 nm thin silicon oxide layer, intrinsic amorphous silicon layer or AlOₓ layer. However, the present disclosure is not limited thereto. In some other embodiments, the passivating tunneling layer 13 may, for example, be a thin layer, e.g., a monolayer, of a passivating atomic species. For example, S or Se can be used as a passivating atomic species on an (100) oriented silicon surface. For example, Cl can be used as a passivating atomic species on an (111) oriented silicon surface. The presence of the passivating tunneling layer 13 on the crystalline silicon substrate rear surface results in a reduction of the surface state density, making the crystalline silicon surface sensitive to the work function of a material provided on the passivating tunneling layer.

The photovoltaic cell 100 further comprises a first transparent conductive layer 14 on top of the passivating tunneling layer 13 at first predetermined locations, the first transparent conductive layer 14 comprising a material with a high work function. The high work function material of the first transparent conductive layer 14 is selected with a suitably high work function to invert a surface region of the n-type silicon substrate 10 and to thereby induce a p⁺ Si/n Si junction or a layer of holes (h⁺) between the inverted surface region and the bulk 10 at the first predetermined locations. Without being bound to any theory, the high work function material may, without a voltage being applied thereto, invert the surface region of the n-type silicon substrate 10 by bending the conduction/valence bands of the n-type substrate such that the valence band energy is higher than the Fermi level at the surface region of the substrate 10. As such, the inverted surface region may conduct predominantly through minority carriers (holes) rather than majority carriers (electrons). The high work function material may have a work function greater than about 4.7 eV, which may approximate a sum of electron affinity of silicon (about 4.15 eV) and half of the silicon band gap (about 1.1 eV). In the photovoltaic cell 100, the inverted surface region forms an emitter region 20. A photovoltaic cell 100 of the present disclosure thus comprises an induced emitter region 20, in which the emitter region 20 comprising minority carrier holes is a field-induced emitter region 20. That is, in the photovoltaic cell 100 of the present disclosure, the emitter region 20 is thus not formed by diffusion of dopants, e.g., p-type dopants, into the substrate, but it is formed by creating (inducing) an inversion layer, e.g., p-type carriers or holes, in a surface region of the silicon substrate. The high work function material of the first transparent conductive layer 14 preferably has a work function greater than about 4.7 eV, e.g., in the range between about 5 eV and 6 eV. Examples of high work function materials that may be used are Mo₂O₃ and NiO, the present disclosure not being limited thereto.

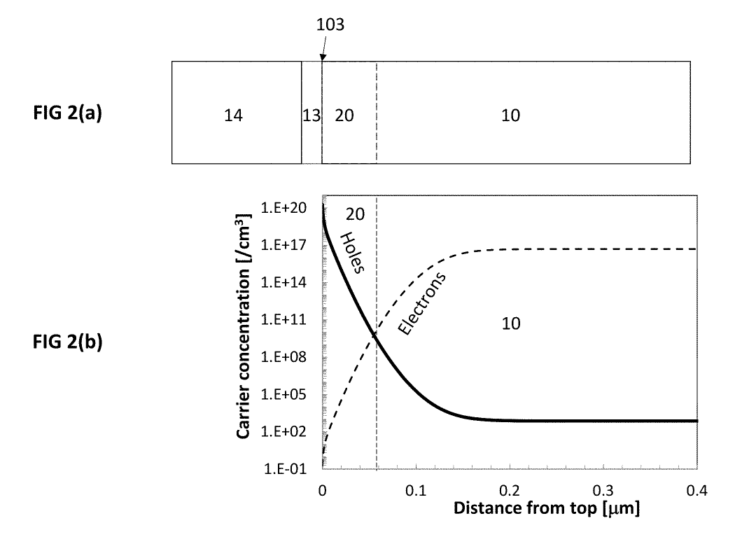

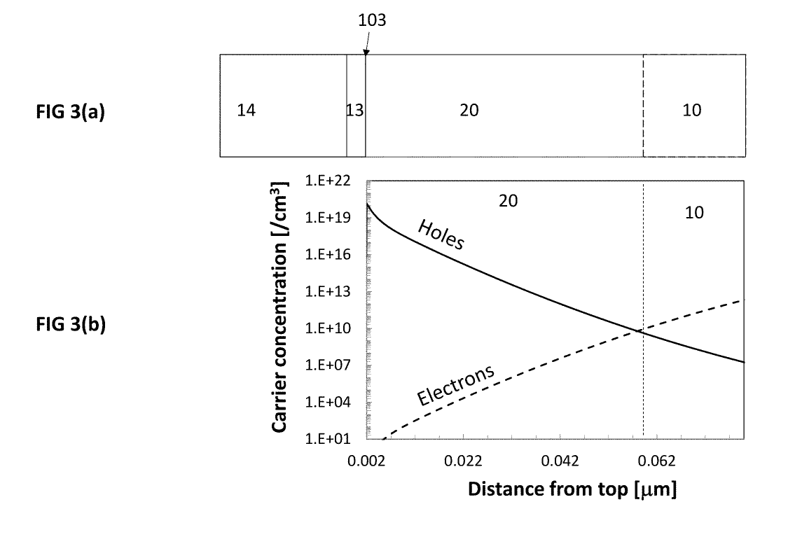

FIGS. 2(a)-2(b) and FIGS. 3(a)-3(b) illustrate the formation of a field-induced p+ Si/n Si junction (e.g., corresponding to an emitter region 20 in a photovoltaic cell according to the present disclosure) in a surface region of an n-type silicon substrate 10, the induced junction resulting from the presence of a stack comprising a thin passivating tunneling layer 13 and a first transparent conductive layer 14 comprising a material with a high work function on the substrate surface.

FIG. 2(a) schematically shows a cross section of an example structure comprising an n-type silicon substrate 10 having a surface 103 coated with a stack of a 2 nm thin SiO₂ layer (as the passivating tunneling layer 13) and a transparent conductive oxide 14 with a work function of 6 eV. The structure shown in FIG. 2(a) is used for simulating (calculating) the effect of providing such a stack on a silicon substrate, as used in a method and device of the present disclosure for inducing an emitter region 20. FIG. 2(b) shows calculated hole and electron concentrations for the structure of FIG. 2(a), illustrating the formation of a p-type inversion layer (emitter region 20) in a surface region of the substrate 10.

FIG. 3(a) schematically shows a cross section of another example structure comprising an n-type substrate 10 coated with a stack of a 2 nm thin intrinsic amorphous silicon layer (as the passivating tunneling layer 13) and a transparent conductive oxide 14 with a work function of 6 eV. The structure shown in FIG. 3(a) is used for simulating (calculating) the effect of providing such a stack on a silicon substrate, as used in a method and device of the present disclosure for inducing an emitter region 20. FIG. 3(b) shows calculated hole and electron concentrations for the structure of FIG. 3(a), illustrating the formation of a p-type inversion layer (emitter region 20) in a surface region of the substrate 10.

The photovoltaic cell 100 further comprises a second transparent conductive layer 15 on top of the passivating tunneling layer 13 at second predetermined locations, corresponding to locations where an electrical contact to the base or bulk 10 is formed (FIG. 1). The second transparent conductive layer 15 comprises a material with a low work function. The low work function material of the second transparent conductive layer 15 is selected with a suitably low work function to induce an n+ region (accumulation region) and thus a high/low n+/n junction or a layer of electrons (e⁻) at the second predetermined locations. Without being bound to any theory, the low work function material may, without a voltage being applied thereto, may accumulate electrons in the surface region of the n-type silicon substrate 10 by bending the conduction/valence bands of the n-type substrate such that the conduction band energy is lower than the Fermi level at the surface region of the substrate 10. As such, the accumulated surface region may conduct predominantly through majority carriers (electrons) rather than minority carrier (holes). The low work function material may have a work function less than about 4.7 eV, which may approximate a sum of electron affinity of silicon (about 4.15 eV) and half of the silicon band gap (about 1.1 eV). In the photovoltaic cell 100 the n+ region forms a back surface field (BSF) region 30 at the second predetermined locations. A photovoltaic cell 100 of the present disclosure thus comprises an induced back surface field region 30, more in particular a field-induced back surface field region 30. In a photovoltaic cell 100 of the present disclosure the back surface field region 30 is thus not formed by diffusion of dopants, e.g., n-type dopants, into the substrate, but it is formed by creating (inducing) an accumulation layer, e.g., n-type carriers or electrons, in a surface region of the silicon substrate. The low work function material of the second transparent conductive layer 15 preferably has a work function less than about 4.7 eV, e.g., in the range between 3.5 eV and 4.5 eV. Examples of low work functions materials that may be used are ITO and Al doped ZnO, the present disclosure not being limited thereto.

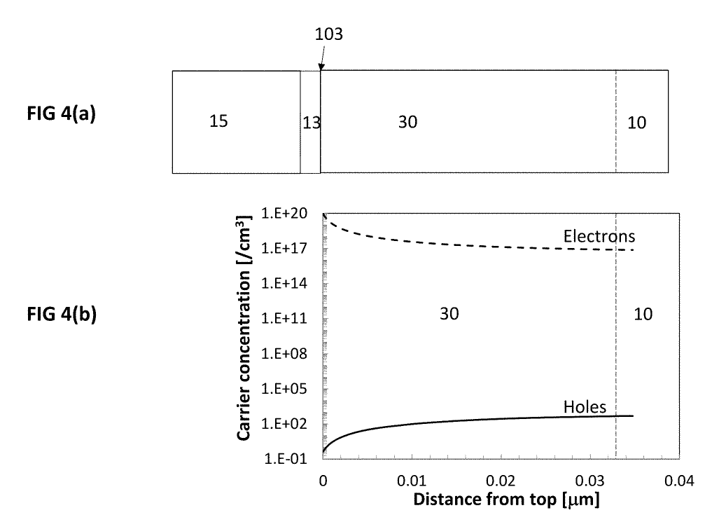

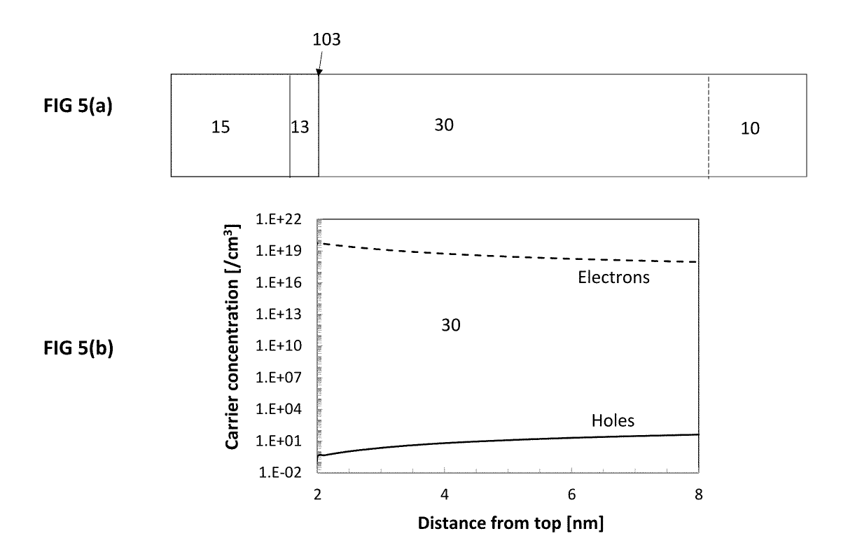

FIG. 4(a)-4(b) and FIG. 5(a)-5(b) illustrate the formation of a field-induced n+ accumulation region (e.g., corresponding to a back surface field region 30 in a photovoltaic cell according to the present disclosure) in a surface region of an n-type silicon substrate 10, the induced n⁺ region resulting from the presence of a stack comprising a thin passivating tunneling layer 13 and a second transparent conductive layer 15 comprising a material with a low work function on the substrate surface.

FIG. 4(a) schematically shows a cross section of an example structure comprising an n-type substrate 10 having a surface 103 coated with a stack of a 2 nm thin SiO₂ layer (passivating tunneling layer 13) and a transparent conductive oxide 15 with a work function of 3.5 eV. The structure shown in FIG. 4(a) is used for simulating (calculating) the effect of providing such a stack on a silicon substrate, as used in a method and device of the present disclosure for inducing a back surface field region 30. FIG. 4(b) shows calculated hole and electron concentrations for the structure of FIG. 4(a), illustrating the formation of an n-type (n⁺) accumulation layer 30 in a surface region of the substrate, in which conduction may be predominantly dominated by holes rather than electrons.

FIG. 5(a) schematically shows a cross section of another example structure comprising an n-type substrate 10 coated with a stack of a 2 nm thin intrinsic amorphous silicon layer (as the passivating tunneling layer 13) and a transparent conductive oxide 15 with a work function of 3.5 eV. The structure shown in FIG. 5(a) is used for simulating (calculating) the effect of providing such a stack on a silicon substrate, as used in a method and device of the present disclosure for inducing a back surface field region 30. FIG. 5(b) shows calculated hole and electron concentrations for the structure of FIG. 5(a), illustrating the formation of an n-type (n+) accumulation layer 30 in a surface region of the substrate 10.

In embodiments of the present disclosure, the first transparent conductive layer 14 and/or the second transparent conductive layer 15 may comprise a stack of two or more transparent conductive layers. For example, the first transparent conductive layer 14 may comprise a stack of a layer made of a material with a high work function and a layer made of a material with a good electrical conductivity. For example, the second transparent conductive layer 15 may comprise a stack of a layer made of a material having a low work function and a layer having a good electrical conductivity, to limit resistive losses.

The thickness of the first transparent conductive layer 14 and the thickness of the second transparent conductive layer 15 may for example be in the range between 50 nm and 200 nm, the present disclosure not being limited thereto.

Referring back to FIG. 1, the first transparent conductive layer 14 and the second transparent conductive layer 15 may function as an optical reflector, when combined with a metal layer (16, 17 in FIG. 1) deposited on top of the transparent conductive layers 14, 15. The materials of the transparent conductive layers are preferably transparent in a range of wavelengths that can be absorbed by the silicon substrate material. Additionally, they are preferably transparent in the infrared wavelength range, which may lead to a reduced warming up of the photovoltaic cells in operation.

As illustrated in FIG. 1, the photovoltaic cell 100 may further comprise a first metal layer 16 on top of the first transparent conductive layer 14 and a second metal layer 17 on top of the second transparent conductive layer 15. The first metal layer 16 and the second metal layer 17 may, for example, comprise a stack of metal layers, such as for example a Ti/Al/Cu stack, the present disclosure not being limited thereto.

It is an advantage that the metal layers 16, 17 may have a higher electrical conductivity than the underlying transparent conductor layers 14, 15, thus forming a low-resistance current path to an external load. The metal layers may further provide a good back surface optical reflectance of the cell.

The back contact photovoltaic cell 100 shown in the example of FIG. 1 thus comprises at the first predetermined locations a first layer stack 41 on the substrate, the first layer stack 41 comprising a passivating tunneling layer 13, a first transparent conductive layer 14 comprising a material with a high work function and a first metal layer 16. The back contact photovoltaic cell 100 shown in the example of FIG. 1 further comprises at the second predetermined locations a second layer stack 42 on the substrate, the second layer stack 42 comprising a passivating tunneling layer 13, a second transparent conductive layer 15 comprising a material with a low work function and a second metal layer 17. While not shown, when viewed in plan-view, the photovoltaic cell 100 may have a plurality of first layer stacks 41 and second layer stacks 42 that alternate with each other and are interlaced. The plurality of first layer stacks 41 may be commonly electrically connected, and the plurality of second layer stacks 42 may be commonly electrically connected.

In a method of fabricating a photovoltaic cell 100 according to an embodiment of the present disclosure as shown in the example of FIG. 1, a passivating tunneling layer 13 is provided at the rear side 102, i.e. on the rear surface, of a crystalline silicon substrate 10. The passivating tunneling layer 13 may be provided on the entire rear surface of the silicon substrate, the present disclosure not being limited thereto. The passivating tunneling layer 13 may for example be a thin dielectric layer such as, for example, a thin silicon oxide layer or a thin intrinsic amorphous silicon layer. The passivating tunneling layer 13 may for example be a monolayer of a passivating atomic species, such as S or Se on (100) oriented silicon surfaces or Cl on (111) oriented silicon surfaces.

In a method of the present disclosure, two different transparent conductive layers or layer stacks are provided on the passivated rear surface of the silicon substrate 10, i.e., on the passivating tunneling layer 13. A first transparent conductive layer 14 comprising a high work function material is provided on top of the passivating tunneling layer 13 at first predetermined locations. The material of the first transparent conductive layer 14 is selected with a suitably high work function to induce an emitter region 20 (inversion region) in the silicon substrate at the first predetermined locations. A second transparent conductive layer 15 comprising a low work function material is provided on top of the passivating tunneling layer 13 at second predetermined locations, corresponding to locations where an electrical contact to the base 10 is to be formed. The material of the second transparent conductive layer 15 may be selected with a suitably low work function to induce a back surface field region (accumulation region) in the silicon substrate at the second predetermined locations. The first predetermined locations and the second predetermined locations are non-overlapping and preferably interdigitated. The first transparent conductive layer 14 and the second transparent conductive layer 15 may be (laterally) separated from each other by an electrically insulating medium such as an air gap (as illustrated in FIG. 1) or a dielectric spacer (not illustrated).

In a method of fabricating a photovoltaic device according to an embodiment of the present disclosure, the first transparent conductive layer 14 and the second transparent conductive layer 15 may, for example, be provided by sputtering (physical vapor deposition) followed by patterning. In some embodiments, the first transparent conductive layer 14 and the second transparent conductive layer 15 are provided using a direct patterning method. For example, in preferred embodiments the transparent conductive layers 14, 15 may be applied by a solution processing method, such as for example inkjet printing or slot die coating. However, the present disclosure is not limited thereto, and other solution based processing methods may be used. For example, self-assembled monolayers may be provided at the first and second predetermined locations, the self-assembled monolayers being matched to the solvents used in the precursors (e.g., inks) used for forming the first and second transparent conductive layers 14, 15. After depositing the transparent conductive layers by solution processing, a heating step is performed, at a temperature that is dependent on the type of solution used for each of the transparent conductive layers.

Next, a first metal layer 16 or a first stack of metal layers 16 is deposited on top of the first transparent conductive layer 14 and a second metal layer 17 or a second stack of metal layers 17 is deposited on top of the second transparent conductive layer 15. After deposition of the first metal layer 16 and after deposition of the second metal layer 17, a patterning step may be done to define and separate (electrically isolate) the different contact regions.

It is an advantage of a fabrication method according to embodiments of the present disclosure that a dopant diffusion step may be omitted. As such, the fabrication method of the present disclosure does not require high temperature processes that may be associated with dopant activation, e.g., annealing processes at temperatures exceeding 600° C. Thus, the back contact photovoltaic cell according to embodiments has a rear side of the n-type substrate that is uniformly doped and does not include further doped regions that serve as an emitter region or a back surface field region. It is an advantage of such low-temperature fabrication process that it may for example be compatible with processing, e.g., rear side processing, on a glass carrier or a glass superstrate. It is an advantage of such low-temperature fabrication process that it allows maintaining a high bulk minority carrier lifetime in the substrate.

The foregoing description details certain embodiments of the disclosure. It will be appreciated, however, that no matter how detailed the foregoing appears in text, the disclosure may be practiced in many ways. It should be noted that the use of particular terminology when describing certain features or aspects of the disclosure should not be taken to imply that the terminology is being re-defined herein to be restricted to including any specific characteristics of the features or aspects of the disclosure with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the invention.

What is claimed is:

1. A back contact photovoltaic cell, comprising:
an n-type silicon substrate having formed on a rear side first layer stacks formed at first locations and second layer stacks formed at second locations different from and non-overlapping with the first locations,
wherein each of the first layer stacks comprises a passivating tunneling layer and a first transparent conductive layer having a first work function, wherein the first transparent conductive layer is configured to induce an inversion region in the n-type silicon substrate at a corresponding one of the first locations, the inversion region forming an emitter region of the back contact photovoltaic cell, and
wherein each of the second layer stacks is configured to induce an accumulation region in the n-type silicon substrate at a corresponding one of the second locations, the accumulation region forming a back-surface field region of the back contact photovoltaic cell.

2. The back contact photovoltaic cell according to claim 1, wherein the first work function is between 5 eV and 6 eV.

3. The back contact photovoltaic cell according to claim 1, wherein each of the second layer stacks comprises a passivating tunneling layer and a second transparent conductive layer having a second work function lower than the first work function, wherein the second transparent conductive layer is configured to induce an accumulation region in the n-type silicon substrate at a corresponding one of the second locations.

4. The back contact photovoltaic cell according to claim 3, wherein the second transparent conductive layer has a work function between 3.5 eV and 4.5 eV.

5. The back contact photovoltaic cell according to claim 1, wherein the passivating tunneling layer is a thin dielectric layer or a monolayer of atoms that passivates the surface of the n-type silicon substrate and is configured to tunnel electrons therethrough.

6. The back contact photovoltaic cell according claim 3, wherein the first layer stack further comprises a first metal layer on the first transparent conductive layer, and wherein the second layer stack further comprises a second metal layer on the second transparent conductive layer.

7. The back contact photovoltaic cell according to claim 1, comprising a textured front side configured to collect photons without having electrical contacts formed thereon.

8. The back contact photovoltaic cell according to claim 7, wherein the first layer stacks and the second layer stacks are alternatingly interdigitated.

9. The back contact photovoltaic cell according to claim 8, wherein the rear side of the n-type substrate is uniformly doped without having a further doped region at the rear side.

10. A method of fabricating a back contact photovoltaic cell, the method comprising:
forming on a rear side of an n-type silicon substrate at first locations first layer stacks and at second locations second layer stacks, the second locations different from and non-overlapping with the first locations,
wherein forming the first layer stacks comprises forming a passivating tunneling layer and a first transparent conductive layer having a first work function configured to induce inversion regions in the n-type silicon substrate at the first locations, the inversion regions forming emitter regions of the back contact photovoltaic cell, and
wherein forming the second layer stacks comprises inducing accumulation regions in the n-type silicon substrate at the second locations, the accumulation region forming back-surface field regions of the back contact photovoltaic cell.

11. The method according to claim 10, wherein forming the second layer stacks comprises forming a passivating tunneling layer and a second transparent conductive layer having a second work function lower than the first work function configured to induce accumulation regions in the n-type silicon substrate at the second locations.

12. The method according to claim 10, wherein the method is performed at temperatures not exceeding 600° C.

13. The method according to claim 10, wherein forming the passivating tunneling layer comprises forming a thin dielectric layer.

14. The method according to claim 10, wherein forming the passivating tunneling layer comprises forming a monolayer of surface-passivating atoms.

15. The method according to claim 11, wherein forming each of the first transparent conductive layer and the second transparent conductive layer comprises solution processing.

16. The method according to claim 11, further comprising forming a first metal layer on the first transparent conductive layer and forming a second metal layer on the second transparent conductive layer.

17. The method according to claim 10, further comprising texturing a front side of the n-type silicon substrate.

18. The method according to claim 10, wherein forming the first layer stacks and the second layer stacks comprises alternatingly interdigitating the first layer stacks and the second layer stacks.

19. The method according to claim 10, further comprising uniformly doping the rear side of the n-type substrate without forming additional doped regions at the rear side.
